(19) United States
(12) Patent Application Publication
(10) Pub. No.: US 2026/0157229 A1
(43) Pub. Date: Jun. 4, 2026

(54) PACKAGE STRUCTURE

(71) Applicant: SILICONWARE PRECISION INDUSTRIES CO., LTD., Taichung City (TW)

(72) Inventors: Shu-Ping YANG, Taichung City (TW); Chia-Hsi HSIEH, Taichung City (TW); Liang-Pin CHEN, Taichung City (TW); Chih-Hung CHEN, Taichung City (TW)

(21) Appl. No.: 19/088,198

(22) Filed: Mar. 24, 2025

(30) Foreign Application Priority Data
Dec. 2, 2024 (TW) 113146598

(51) Int. Cl. H01L 25/16; G02B 6/42; H01L 23/00; H01L 23/14; H01L 23/367; H01L 23/498; H01L 23/538

(52) U.S. Cl. CPC H10W 90/00; G02B 6/4204; G02B 6/4269; H10W 40/22; H10W 70/611; H10W 90/401; H10W 90/701; H10W 70/685; H10W 70/698; H10W 72/877; H10W 90/724; H10W 90/736

(57) ABSTRACT

A package structure includes a substrate structure, an optoelectronic module, a heat sink and an optical communication unit. The heat sink and the optoelectronic module are disposed on the substrate structure. The heat sink has a slot, the optoelectronic module has a photonic component, and the slot is used for the optical communication unit to pass through and to connect to the photonic component, so that the heat dissipation efficiency is improved and the distance of signal transmission is reduced.

### CROSS-REFERENCE TO RELATED APPLICATIONS

The present application is based upon and claims the right of priority to TW Patent Application No. 113146598, filed on Dec. 2, 2024, the disclosure of which is hereby incorporated by reference herein in its entirety for all purposes.

### BACKGROUND

### 1. Technical Field

The present disclosure relates to a semiconductor device, and more particularly, to a package structure used for optical communication.

### 2. Description of Related Art

With the vigorous development of the electronics industry, electronic products are gradually developing towards multi-function and high performance. At present, the application of fifth-generation (5G) communication technology has expanded to fields such as Internet of Things (IoT), Industrial Internet of Things (IIoT), cloud, artificial intelligence (AI), autonomous car, medical, etc. As the application level expands, very large amounts of data that need to be transmitted, computed and stored efficiently will be generated in the process. Therefore, the need for data transmission for large-scale data centers and cloud servers has emerged substantially in recent years, and the industry has begun to enter the field of optical communication and to use “light” instead of “electricity” as the carrier of data transmission. In this background, co-packaged optics has become the trend of development for future semiconductor and packaging technology.

FIG. 1 is a schematic cross-sectional view of a semiconductor package 1 of conventional co-packaged optics. An electronic component 11, an electronic integrated circuit (EIC) component 12 and a photonic integrated circuit (PIC) component 13 are disposed respectively on a substrate 10 of the semiconductor package 1, and a side end of the photonic integrated circuit component 13 is connected to an optical fiber 14.

The electronic component 11 and the electronic integrated circuit component 12 are disposed on the substrate 10 via a first circuit structure 15, and the photonic integrated circuit component 13 is disposed on the substrate 10 via a second circuit structure 16. In other words, the electronic component 11 and the electronic integrated circuit component 12 need the first circuit structure 15, the substrate 10 and the second circuit structure 16 so as to be electrically connected to the photonic integrated circuit component 13.

However, the path of electrical signal transmission of the semiconductor package 1 of conventional co-packaged optics is too long, which causes signal loss, so that the semiconductor package 1 of conventional co-packaged optics cannot meet the rapid and substantial growth need of data transmission for future technology and products. In addition, when there is a demand for transmitting large amounts of data, and if the heat generated during operation cannot be effectively dissipated, the operation performance and service life of the semiconductor package 1 of conventional co-packaged optics will be affected.

Therefore, how to overcome the above-mentioned problems of the prior art has become an urgent issue to be solved.

### SUMMARY

The present disclosure provides a package structure, which comprises: a substrate structure; an optoelectronic module disposed on the substrate structure and having a photonic component; a heat sink disposed on the substrate structure and formed with a slot; and an optical communication unit disposed on the substrate structure and connected to the photonic component via the slot.

In the aforementioned package structure, the optoelectronic module is electrically connected to the substrate structure via a plurality of conductive bumps.

In the aforementioned package structure, the optoelectronic module includes a routing structure, a semiconductor component and an electronic component disposed on a side of the routing structure, and the photonic component disposed on another side of the routing structure.

In the aforementioned package structure, the semiconductor component is an electronic integrated circuit chip, and the semiconductor component is disposed on a first side of the routing structure and electrically connected to the routing structure.

In the aforementioned package structure, the photonic component is a photonic integrated circuit chip, and the photonic component is disposed on a second side of the routing structure and electrically connected to the routing structure.

In the aforementioned package structure, the heat sink includes a cover portion and a support portion, and the support portion is disposed on a periphery of the cover portion, so that an accommodating space is formed and surrounded by the cover portion and the support portion.

In the aforementioned package structure, the heat sink is erected on the substrate structure via the support portion, the optoelectronic module is covered by the cover portion, and the optoelectronic module is accommodated in the accommodating space.

In the aforementioned package structure, the optical communication unit is a fiber array unit, and the optical communication unit is used to connect to an optical fiber.

In the aforementioned package structure, a planar size of the slot of the heat sink is larger than a planar size of the optical communication unit.

The aforementioned package structure further comprises a plurality of conductive components disposed on a bottom side of the substrate structure.

In the aforementioned package structure, the optical communication unit passes through the slot and is connected to the photonic component.

In the aforementioned package structure, the photonic component and the optical communication unit both extend into the slot and are connected to each other.

Therefore, the package structure of the present disclosure primarily includes a substrate structure and an optoelectronic module, a heat sink and an optical communication unit disposed on the substrate structure, wherein the optoelectronic module has a routing structure, a semiconductor component and an electronic component disposed on a first side of the routing structure, and a photonic component disposed on a second side of the routing structure, so that the semiconductor component and the electronic component can be electrically connected to the photonic component via the routing structure directly so as to reduce the distance of signal transmission. Meanwhile, the heat sink has a slot, and the slot is used for the optical communication unit to pass through and to connect to the photonic component, so that the connection efficiency between the optical communication unit and the photonic component can be improved, and the heat dissipation efficiency can also be improved.

### BRIEF DESCRIPTION OF THE DRAWINGS

FIG. 1 is a schematic cross-sectional view of a semiconductor package of conventional co-packaged optics.

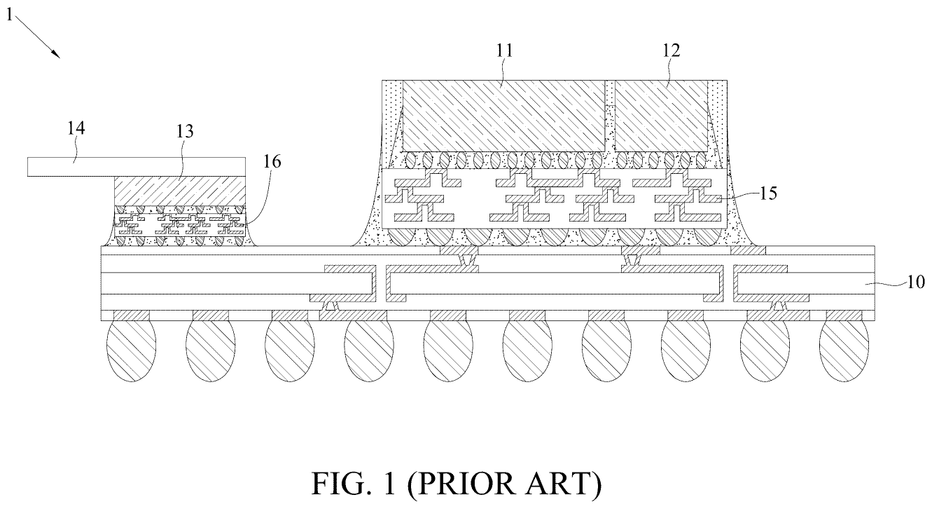

FIG. 2 is a schematic cross-sectional view of a package structure according to a first embodiment of the present disclosure.

FIG. 3 is a partial schematic cross-sectional view of the package structure of the present disclosure.

FIG. 4 is a schematic cross-sectional view of a package structure according to a second embodiment of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” “one,” “at least one” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

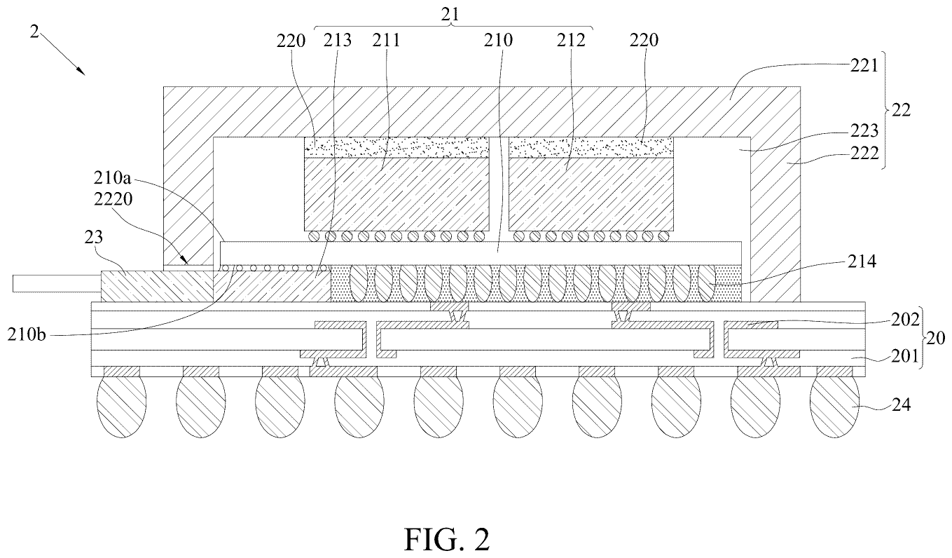

Please refer to FIG. 2, which is a schematic cross-sectional view of a package structure 2 of the present disclosure. As shown in FIG. 2, the package structure 2 includes a substrate structure 20, an optoelectronic module 21 (e.g., an optical engine module) disposed on the substrate structure 20, a heat sink 22 disposed on the substrate structure 20, and an optical communication unit 23 disposed on the substrate structure 20 and connected to the optoelectronic module 21.

The substrate structure 20 is, for example, a package substrate with a core layer or a coreless package substrate. The substrate structure 20 includes at least one insulation layer 201 and at least one circuit layer 202 bonded to the insulation layer 201. The insulation layer 201 is made of dielectric material such as polybenzoxazole (PBO), polyimide (PI), prepreg (PP), or the like. The circuit layer 202 can be made of copper or other conductive material.

The optoelectronic module 21 includes a routing structure 210 (e.g., a wiring structure), a semiconductor component 211 and an electronic component 212 disposed on a side of the routing structure 210, and a photonic component 213 disposed on another side of the routing structure 210. The optoelectronic module 21 can be electrically connected to the substrate structure 20 via a plurality of conductive bumps 214 such as solder bumps, copper bumps, or the like.

The routing structure 210 has a first side 210a and a second side 210b opposite to the first side 210a. The routing structure 210 includes at least one insulating layer and at least one routing/wiring layer formed on the insulating layer, such as of a redistribution layer (RDL) specification.

The semiconductor component 211 is, for example, an electronic integrated circuit (EIC) chip. The semiconductor component 211 is disposed on the first side 210a of the routing structure 210 and is electrically connected to the routing structure 210.

The electronic component 212 is disposed on the first side 210a of the routing structure 210 and is electrically connected to the routing structure 210. The electronic component 212 is, for example, an active component such as a switch chip, a system on a chip (SOC), a high bandwidth memory (HBM) chip, or another kind of functional chip. Alternatively, the electronic component 212 can be a passive component such as a resistor, a capacitor, or an inductor.

The photonic component 213 is, for example, a photonic integrated circuit (PIC) chip. The photonic component 213 is disposed on the second side 210b of the routing structure 210 and is electrically connected to the routing structure 210, so that the semiconductor component 211 and the electronic component 212 can be electrically connected to the photonic component 213 via the routing structure 210 directly.

The heat sink 22 is disposed on the substrate structure 20 and covers the optoelectronic module 21.

The heat sink 22 includes a cover portion 221 and a support portion 222, wherein the support portion 222 is disposed on the periphery of the cover portion 221, so that an accommodating space 223 is formed and surrounded by the cover portion 221 and the support portion 222. The heat sink 22 can be erected on the substrate structure 20 via the support portion 222, the optoelectronic module 21 is covered by the cover portion 221, and the optoelectronic module 21 is accommodated in the accommodating space 223. In addition, the support portion 222 is formed with a slot 2220 corresponding to the position of the photonic component 213 of the optoelectronic module 21, wherein the slot 2220 is served as an optical signal channel.

Additionally, the cover portion 221 of the heat sink 22 can be disposed on the semiconductor component 211 and the electronic component 212 via a thermal interface material (TIM) layer 220 so as to efficiently dissipate the heat generated during the operation of the semiconductor component 211 and the electronic component 212.

The optical communication unit 23 is disposed on the substrate structure 20 and is connected to the photonic component 213 of the optoelectronic module 21 via the slot 2220 of the heat sink 22. The optical communication unit 23 is, for example, a fiber array unit (FAU), and the optical communication unit 23 is used to connect to at least one optical fiber.

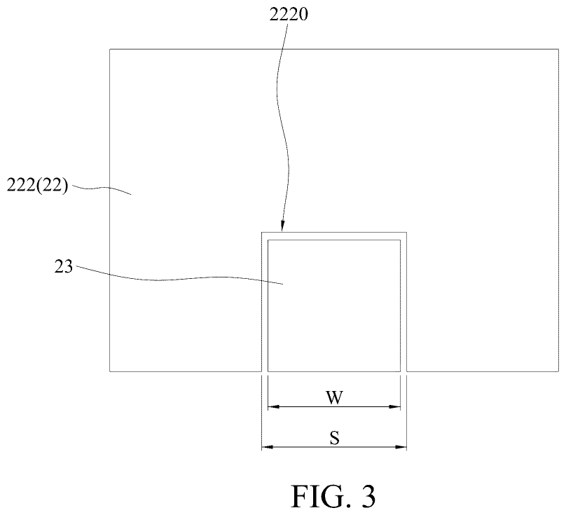

Please also refer to FIG. 3, a planar size of the slot 2220 of the heat sink 22 is larger than a planar size of the optical communication unit 23, so that the optical communication unit 23 can easily pass through the slot 2220 and connect to the photonic component 213.

In an embodiment, the optical communication unit 23 has a width W, the slot 2220 of the heat sink 22 has a width S, and the difference between the width W and the width S is less than 10 μm, which facilitates the alignment between the optical communication unit 23 and the photonic component 213 so as to improve connection efficiency.

In addition, a plurality of conductive components 24 such as solder balls can be disposed on the bottom side of the substrate structure 20, in order to connect to other electronic devices (not shown).

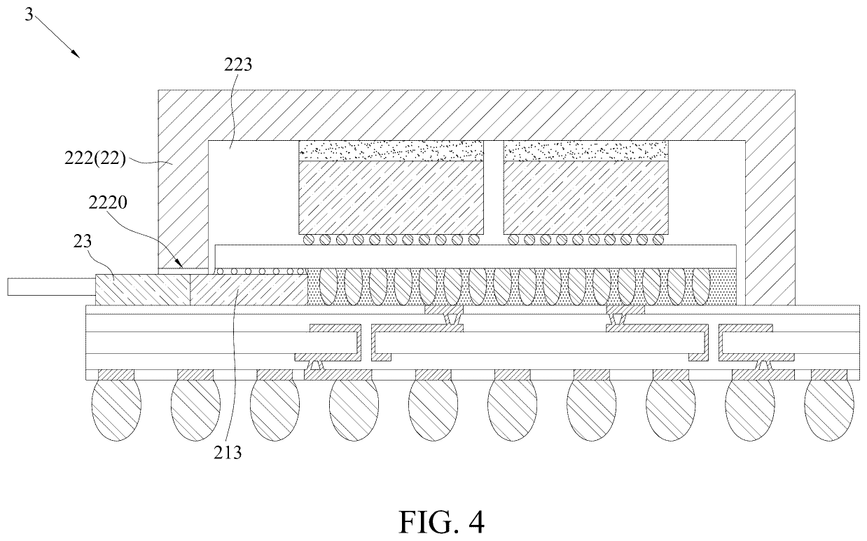

Please refer to FIG. 4, which is a schematic cross-sectional view of a package structure 3 according to a second embodiment of the present disclosure.

The second embodiment is roughly the same as the first embodiment. The main difference between the second embodiment and the first embodiment is that in the package structure 3 of the second embodiment of the present disclosure, the photonic component 213 extends into the slot 2220 of the heat sink 22 from the inner side of the heat sink 22 (the accommodating space 223); meanwhile, the optical communication unit 23 extends into the slot 2220 of the heat sink 22 from the outer side of the heat sink 22 and is connected to the photonic component 213. That is, the photonic component 213 and the optical communication unit 23 both extend into the slot 2220, which facilitates the alignment and connection between the photonic component 213 and the optical communication unit 23.

In summary, the package structure of the present disclosure primarily includes a substrate structure and an optoelectronic module, a heat sink and an optical communication unit disposed on the substrate structure, wherein the optoelectronic module has a routing structure, a semiconductor component and an electronic component disposed on a first side of the routing structure, and a photonic component disposed on a second side of the routing structure, so that the semiconductor component and the electronic component can be electrically connected to the photonic component via the routing structure directly so as to reduce the distance of signal transmission. Meanwhile, the heat sink has a slot, and the slot is used for the optical communication unit to pass through and to connect to the photonic component, so that the connection efficiency between the optical communication unit and the photonic component can be improved, and the heat dissipation efficiency can also be improved.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A package structure, comprising:
a substrate structure;
an optoelectronic module disposed on the substrate structure and having a photonic component;
a heat sink disposed on the substrate structure and formed with a slot; and
an optical communication unit disposed on the substrate structure and connected to the photonic component via the slot.

2. The package structure of claim 1, wherein the optoelectronic module is electrically connected to the substrate structure via a plurality of conductive bumps.

3. The package structure of claim 1, wherein the optoelectronic module includes a routing structure, a semiconductor component and an electronic component disposed on a side of the routing structure, and the photonic component disposed on another side of the routing structure.

4. The package structure of claim 3, wherein the semiconductor component is an electronic integrated circuit chip, and the semiconductor component is disposed on a first side of the routing structure and electrically connected to the routing structure.

5. The package structure of claim 3, wherein the photonic component is a photonic integrated circuit chip, and the photonic component is disposed on a second side of the routing structure and electrically connected to the routing structure.

6. The package structure of claim 1, wherein the heat sink includes a cover portion and a support portion, and the support portion is disposed on a periphery of the cover portion, so that an accommodating space is formed and surrounded by the cover portion and the support portion.

7. The package structure of claim 6, wherein the heat sink is erected on the substrate structure via the support portion, the optoelectronic module is covered by the cover portion, and the optoelectronic module is accommodated in the accommodating space.

8. The package structure of claim 1, wherein the optical communication unit is a fiber array unit, and the optical communication unit is used to connect to an optical fiber.

9. The package structure of claim 1, wherein a planar size of the slot of the heat sink is larger than a planar size of the optical communication unit.

10. The package structure of claim 1, further comprising a plurality of conductive components disposed on a bottom side of the substrate structure.

11. The package structure of claim 1, wherein the optical communication unit passes through the slot and is connected to the photonic component.

12. The package structure of claim 1, wherein the photonic component and the optical communication unit both extend into the slot and are connected to each other.
